(19) United States
(12) Patent Application Publication
(10) Pub. No.: US 2007/0103034 A1
(43) Pub. Date: May 10, 2007

(54) Acoustic driver assembly with increased head mass displacement amplitude

(75) Inventors: Daniel A. Phillips, Grass Valley, CA (US); Brant James Callahan, Grass Valley, CA (US)

Correspondence Address: PATENT LAW OFFICE OF DAVID G. BECK, P. O. BOX 1146, MILL VALLEY, CA, 94942, US

(73) Assignee: Impulse Devices Inc., Grass Valley, CA (US)

(21) Appl. No.: 11/267,527

(22) Filed: Nov. 4, 2005

(51) Int. Cl. H01L 41/08

(52) U.S. Cl. 310/328

(57) ABSTRACT

An acoustic driver horn that is integral to a wall of a cavitation chamber is provided. The horn design is applicable to any of a variety of cavitation chamber configurations, including spherical, cylindrical, and rectangular chambers. Although a variety of driver assemblies can be coupled to the driver horn, preferably the acoustic driver assembly includes a head mass, a tail mass, and at least one transducer, typically a piezoelectric transducer, and preferably a pair of piezoelectric transducers. A groove in the cavitation chamber wall defines the driver horn and separates it from the remaining portion of the cavitation chamber wall. Due to the thinning of the wall around the horn, the driver that is attached to the horn is able to more effectively couple its energy into the cavitation fluid within the chamber.

### FIELD OF THE INVENTION

The present invention relates generally to sonoluminescence and, more particularly, to an apparatus for increasing the displacement amplitude in a cavitation chamber coupled to an acoustic driver.

### BACKGROUND OF THE INVENTION

Sonoluminescence is a well-known phenomena discovered in the 1930's in which light is generated when a liquid is cavitated. Although a variety of techniques for cavitating the liquid are known (e.g., spark discharge, laser pulse, flowing the liquid through a Venturi tube), one of the most common techniques is through the application of high intensity sound waves.

In essence, the cavitation process consists of three stages; bubble formation, growth and subsequent collapse. The bubble or bubbles cavitated during this process absorb the applied energy, for example sound energy, and then release the energy in the form of light emission during an extremely brief period of time. The intensity of the generated light depends on a variety of factors including the physical properties of the liquid (e.g., density, surface tension, vapor pressure, chemical structure, temperature, hydrostatic pressure, etc.) and the applied energy (e.g., sound wave amplitude, sound wave frequency, etc.).

Although it is generally recognized that during the collapse of a cavitating bubble extremely high temperature plasmas are developed, leading to the observed sonoluminescence effect, many aspects of the phenomena have not yet been characterized. As such, the phenomena is at the heart of a considerable amount of research as scientists attempt to not only completely characterize the phenomena (e.g., effects of pressure on the cavitating medium), but also its many applications (e.g., sonochemistry, chemical detoxification, ultrasonic cleaning, etc.).

Although acoustic drivers are commonly used to drive the cavitation process, there is little information about methods of coupling the acoustic energy to the cavitation chamber. For example, in an article entitled Ambient Pressure Effect on Single-Bubble Sonoluminescence by Dan et al. published in vol. 83, no. 9 of Physical Review Letters, the authors describe their study of the effects of ambient pressure on bubble dynamics and single bubble sonoluminescence. Although the authors describe their experimental apparatus in some detail, they only disclose that a piezoelectric transducer was used at the fundamental frequency of the chamber, not how the transducer couples its energy into the chamber.

U.S. Pat. No. 4,333,796 discloses a cavitation chamber that is generally cylindrical although the inventors note that other shapes, such as spherical, can also be used. As disclosed, the chamber is comprised of a refractory metal such as tungsten, titanium, molybdenum, rhenium or some alloy thereof and the cavitation medium is a liquid metal such as lithium or an alloy thereof. Surrounding the cavitation chamber is a housing which is purportedly used as a neutron and tritium shield. Projecting through both the outer housing and the cavitation chamber walls are a number of acoustic horns, each of the acoustic horns being coupled to a transducer which supplies the mechanical energy to the associated horn. The specification only discloses that the horns, through the use of flanges, are secured to the chamber/housing walls in such a way as to provide a seal and that the transducers are mounted to the outer ends of the horns.

U.S. Pat. No. 5,658,534 discloses a sonochemical apparatus consisting of a stainless steel tube about which ultrasonic transducers are affixed. The patent provides considerable detail as to the method of coupling the transducers to the tube. In particular, the patent discloses a transducer fixed to a cylindrical half-wavelength coupler by a stud, the coupler being clamped within a stainless steel collar welded to the outside of the sonochemical tube. The collars allow circulation of oil through the collar and an external heat exchanger. The abutting faces of the coupler and the transducer assembly are smooth and flat. The energy produced by the transducer passes through the coupler into the oil and then from the oil into the wall of the sonochemical tube.

U.S. Pat. No. 5,659,173 discloses a sonoluminescence system that uses a transparent spherical flask. The spherical flask is not described in detail, although the specification discloses that flasks of Pyrex®, Kontes®, and glass were used with sizes ranging from 10 milliliters to 5 liters. The drivers as well as a microphone piezoelectric were simply epoxied to the exterior surface of the chamber.

U.S. Pat. No. 5,858,104 discloses a shock wave chamber partially filled with a liquid. The remaining portion of the chamber is filled with gas which can be pressurized by a connected pressure source. Acoustic transducers are used to position an object within the chamber while another transducer delivers a compressional acoustic shock wave into the liquid. A flexible membrane separating the liquid from the gas reflects the compressional shock wave as a dilation wave focused on the location of the object about which a bubble is formed. The patent simply discloses that the transducers are mounted in the chamber walls without stating how the transducers are to be mounted.

U.S. Pat. No. 5,994,818 discloses a transducer assembly for use with tubular resonator cavity rather than a cavitation chamber. The assembly includes a piezoelectric transducer coupled to a cylindrical shaped transducer block. The transducer block is coupled via a central threaded bolt to a wave guide which, in turn, is coupled to the tubular resonator cavity. The transducer, transducer block, wave guide and resonator cavity are co-axial along a common central longitudinal axis. The outer surface of the end of the wave guide and the inner surface of the end of the resonator cavity are each threaded, thus allowing the wave guide to be threadably and rigidly coupled to the resonator cavity.

U.S. Pat. No. 6,361,747 discloses an acoustic cavitation reactor in which the reactor chamber is comprised of a flexible tube. The liquid to be treated circulates through the tube. Electroacoustic transducers are radially and uniformly distributed around the tube, each of the electroacoustic transducers having a prismatic bar shape. A film of lubricant is interposed between the transducer heads and the wall of the tube to help couple the acoustic energy into the tube.

U.S. Pat. No. 6,956,316 discloses an acoustic driver assembly for use with a spherical cavitation chamber. The surface of the driver's head mass that is coupled to the chamber has a spherical curvature greater than the spherical curvature of the external surface of the chamber, thus providing a ring of contact between the acoustic driver and the cavitation chamber. The area of the contact ring can be controlled, for example by chamfering a portion of the head mass such that the chamfered surface has the same curvature as the external surface of the chamber.

PCT Application No. US00/32092 discloses several driver assembly configurations for use with a solid cavitation reactor. The disclosed reactor system is comprised of a solid spherical reactor with multiple integral extensions surrounded by a high pressure enclosure. Individual driver assemblies are coupled to each of the reactor's integral extensions, the coupling means sealed to the reactor's enclosure in order to maintain the high pressure characteristics of the enclosure.

### SUMMARY OF THE INVENTION

The present invention provides an acoustic driver horn that is integral to a wall of a cavitation chamber. The horn design is applicable to any of a variety of cavitation chamber configurations, including spherical, cylindrical, and rectangular chambers. Although a variety of driver assemblies can be coupled to the driver horn, preferably the acoustic driver assembly includes a head mass, a tail mass, and at least one transducer, typically a piezoelectric transducer, and preferably a pair of piezoelectric transducers.

The external surface of the cavitation chamber wall to which the acoustic driver assembly is attached includes a groove, the groove surrounding a portion of the wall which acts as a horn for the attached acoustic driver assembly. Due to the thinning of the wall around the horn region, the head mass is capable of greater displacement than would otherwise be possible for a given driver energy. As a result, the driver assembly is able to more effectively couple its energy into the cavitation fluid within the chamber.

In one embodiment of the invention, the head mass of the acoustic driver is separate from the integral horn region which is defined by the groove within the external surface of the chamber. As a result of this configuration, the head mass can be shaped and/or have a different diameter from that of the horn region. Alternately the head mass and the horn region can be combined into a single structure.

In one embodiment the acoustic driver assembly is attached to the cavitation chamber with a threaded means (e.g., all-thread/nut assembly, bolt, etc.). The same threaded means is used to assemble the driver. If the acoustic driver head mass is separate from the horn region, a pair of threaded means can be used, one to hold together the head mass and the horn, and another to couple the remaining portions of the driver assembly to the head mass. Alternately a single threaded means can be used, both to hold together the head mass and the horn and to assemble the driver.

A further understanding of the nature and advantages of the present invention may be realized by reference to the remaining portions of the specification and the drawings.

### BRIEF DESCRIPTION OF THE DRAWINGS

FIG. 1 is a perspective view of a driver assembly in accordance with the prior art;

FIG. 2 is a cross-sectional view of the driver assembly shown in FIG. 1, attached to the wall of a cavitation chamber;

FIG. 3 is an illustration of a cavitation chamber and driver assembly according to the invention;

FIG. 4 is an illustration of the embodiment shown in FIG. 3 utilizing a different means for attaching the driver assembly to the cavitation chamber;

FIG. 5 is an end view of the end cap shown in FIGS. 3 and 4;

FIG. 6 is an illustration of a cavitation chamber and driver assembly similar to that of FIG. 3, except for the width of the groove surrounding the driver horn;

FIG. 7 is an illustration of a cavitation chamber and driver assembly similar to that of FIG. 3, except that the driver horn and the head mass have different diameters;

FIG. 8 is an illustration of a cavitation chamber and driver assembly similar to that of FIG. 3, except for the use of a single piece head mass/horn assembly;

FIG. 9 is an illustration of a cavitation chamber and driver assembly similar to that of FIG. 8, except for the thickness of the head mass/horn assembly;

FIG. 10 is an illustration of a cavitation chamber and driver assembly similar to that of FIG. 3, except for the use of a shaped head mass in the driver assembly;

FIG. 11 is an illustration of a cavitation chamber and driver assembly similar to that of FIG. 3, except for the use of a magnetostrictive transducer assembly; and

FIG. 12 is an illustration of an alternate embodiment of the invention utilizing a spherical cavitation chamber and a pair of driver assemblies.

### DESCRIPTION OF THE SPECIFIC EMBODIMENTS

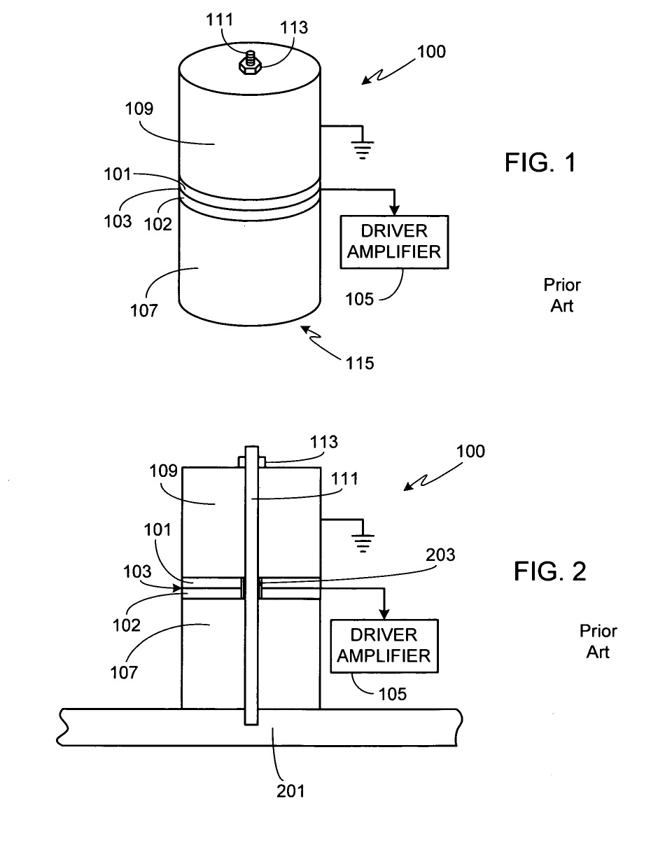

FIG. 1 is a perspective view of a driver assembly 100 in accordance with the prior art. FIG. 2 is a cross-sectional view of the same driver assembly coupled to a wall portion 201 of a cavitation chamber.

Preferably piezoelectric transducers are used in driver 100 although magnetostrictive transducers can also be used, magnetostrictive transducers typically preferred when lower frequencies are desired. A combination of piezoelectric and magnetostrictive transducers can also be used, for example as a means of providing greater frequency bandwidth.

Although driver assembly 100 can use a single piezoelectric transducer, preferably assembly 100 uses a pair of piezoelectric transducer rings 101 and 102 poled in opposite directions. By using a pair of transducers in which the adjacent surfaces of the two crystals have the same polarity, potential grounding problems are minimized. An electrode disc 103 is located between transducer rings 101 and 102 which, during operation, is coupled to the driver power amplifier 105.

The transducer pair is sandwiched between a head mass 107 and a tail mass 109. Head mass 107 and tail mass 109 can be fabricated from the same material and be of equal mass. Alternately head mass 107 and tail mass 109 can be fabricated from different materials. In yet other alternatives, head mass 107 and tail mass 109 can have different masses and/or different mass diameters and/or different mass lengths. For example tail mass 109 can be much larger than head mass 107.

Typically driver assembly 100 is assembled about a centrally located all-thread 111 which is screwed directly into the wall 201 of the cavitation chamber. A nut 113 holds the assembly together. If all-thread 111 does not pass through the entire chamber wall as shown, the internal surface of the cavitation chamber remains smooth, thus insuring that there are neither gas nor liquid leaks at the point of driver attachment. It is understood that all-thread 111 and nut 113 can be replaced with a bolt or other means of attachment. An insulating sleeve 203 isolates all-thread 111, preventing it from shorting electrode 103.

For purposes of illustration only, a typical driver assembly is approximately 2.5 inches in diameter with a head mass and a tail mass each weighing approximately 5 pounds. Both the head mass and the tail mass may be fabricated from 17-4 PH stainless steel. Suitable piezoelectric transducers are fabricated by Channel Industries of Santa Barbara, California. If the driver assembly is attached to the chamber with an all-thread, the all-thread may be on the order of a 0.5 inch all-thread and the assembly can be tightened to a level of 120 ft-lbs. If an insulating sleeve is used, as preferred, it is typically fabricated from Teflon.

As previously noted, attaching the driver assembly to the outside of the cavitation chamber is advantageous as it eliminates a potential source of gas and fluid leaks, assuming that the means used to couple the driver to the chamber does not protrude through the chamber wall. A disadvantage, however, of this approach is that the energy produced by the driver is dampened by the chamber wall, the degree of dampening being directly proportional to the thickness of the wall. Accordingly even though thick walls can handle higher pressures and are generally better from a fabrication and assembly point of view, for example providing a convenient mounting location for drivers, such walls can significantly decrease the driver coupling efficiency.

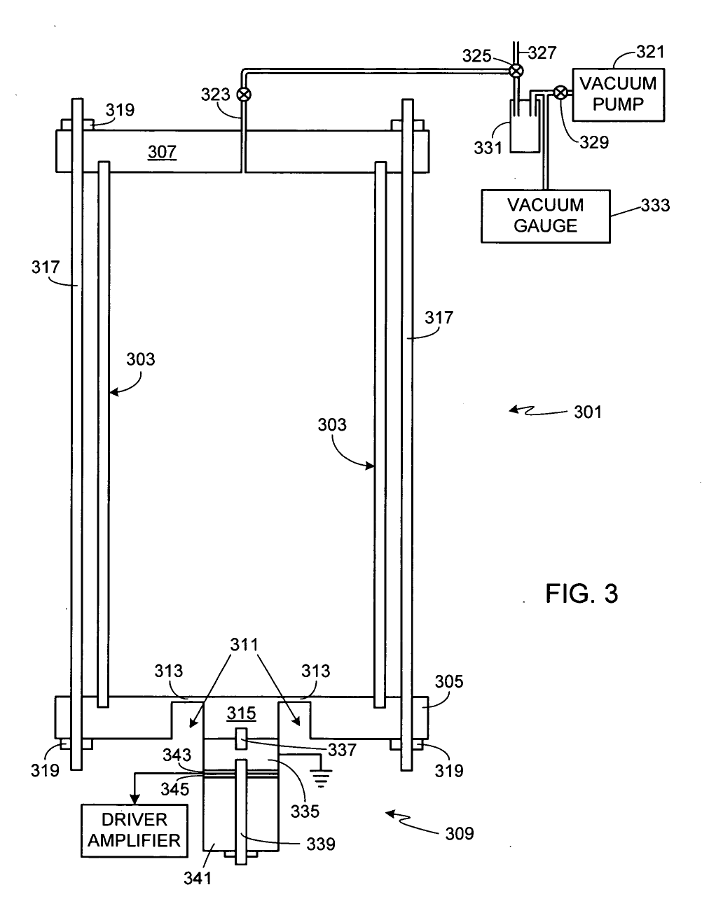

FIG. 3 is an illustration of a cavitation chamber and driver assembly according to the invention. In this embodiment, chamber 301 is comprised of a cylindrical wall portion 303 and a pair of end caps 305 and 307. Coupled to end cap 305 is a driver assembly 309. In accordance with the invention and as described in further detail below, end cap 305 includes a groove 311 which leaves only a thin wall 313 surrounding the portion of the end cap to which driver assembly 309 is coupled. By making wall portions 313 less rigid than the remaining portions of the end cap, portion 315 of end cap 305 is capable of greater displacement than would otherwise be possible for a given driver energy. Additionally groove 311 helps to channel the acoustic energy from driver assembly 309 into the chamber. As a result, driver assembly 309 is able to more effectively couple its energy into chamber 301 and the cavitation fluid contained within the chamber.

Although the chamber shown in the embodiment of FIG. 3 is a cylindrical chamber, it should be appreciated that the invention is not limited to a particular configuration. Particular configurations are typically selected to accommodate a specific cavitation process and its corresponding process parameters (e.g., cavitation fluid, pressure, temperature, reactants, etc.). Examples of other configurations include spherical chambers, hourglass-shaped chambers, conical chambers, cubical chambers, rectangular chambers, irregularly-shaped chambers, etc. One method of fabricating a suitable spherical chamber is described in detail in co-pending U.S. patent application Ser. No. 10/925,070, filed Aug. 23, 2004, entitled Method of Fabricating a Spherical Cavitation Chamber, the entire disclosure of which is incorporated herein for any and all purposes. Examples of hourglass-shaped chambers are provided in co-pending U.S. patent application Ser. Nos. 11/140,175, filed May 27, 2005, entitled Hourglass-Shaped Cavitation Chamber, and 11/149,791, filed Jun. 9, 2005, entitled Hourglass-Shaped Cavitation Chamber with Spherical Lobes, the entire disclosures of which are incorporated herein for any and all purposes.

The cavitation chamber of the invention can be fabricated from any of a variety of materials, or any combination of materials, although the surface to which the cavitation driver (or drivers) is attached should be of a machinable material, thus allowing the region of the wall surrounding the wall portion to which the driver is attached to be thinned in accordance with the invention. Other considerations for material selection are the desired operating pressure and temperature of the chamber and system. In addition, preferably the material or materials selected for the cavitation chamber are relatively corrosion resistant to the intended cavitation fluid, thus allowing the chamber to be used repeatedly.

The materials used to fabricate the cavitation chamber can be selected to simplify viewing of the sonoluminescence phenomena, for example utilizing a transparent material such as glass, borosilicate glass, or quartz glass (e.g., Pyrex®). Alternately the cavitation chamber can be fabricated from a more robust material (e.g., 17-4 precipitation hardened stainless steel) and one which is preferably machinable, thus simplifying fabrication. Alternately a portion of the chamber can be fabricated from one material while other portions of the chamber can be fabricated from one or more different materials. For example, in the preferred embodiment illustrated in FIG. 3, cylindrical portion 303 is fabricated from a transparent material (e.g., glass) while end caps 305 and 307 are fabricated from a metal (e.g., aluminum), the assembly being held together with multiple all-threads 317 and nuts 319.

The selected dimensions of the cavitation chamber depend on many factors, including the cost of the cavitation fluid, chamber fabrication issues, operating temperature and frequency, sound speed, and the cavitation driver capabilities. In general, small chambers are preferred for situations in which it is desirable to limit the amount of the cavitation medium or in which driver input energy is limited while large chambers (e.g., 10 inches or greater) are preferred as a means of simplifying experimental set-up and event observation or when high energy reactions or large numbers of low energy reactions are being driven within the chamber. Thick chamber walls are preferred in order to accommodate high pressures.

In order to efficiently achieve high energy density (e.g., temperature) cavitation induced implosions within the cavitation fluid within the cavitation chamber, preferably the cavitation fluid is first adequately degassed of unwanted contaminants. Without sufficient degassing, gas within the cavitation fluid will impede the cavitation process by decreasing the maximum rate of collapse as well as the peak stagnation pressure and temperature of the plasma within the cavitating bubbles. It will be understood that the term “gas”, as used herein, refers to any of a variety of gases that are trapped within the cavitation fluid, these gases typically reflecting the gases contained within air (e.g., oxygen, nitrogen, argon, etc.). In contrast, “vapor” only refers to molecules of the cavitation fluid that are in the gaseous phase.

The present invention is not limited to a particular degassing technique. In the preferred embodiment, degassing is performed with a vacuum pump 321 that is coupled to chamber 301 via conduit 323. In an alternate embodiment, degassing can be performed within a separate degassing reservoir in which the cavitation fluid is degassed prior to filling the cavitation chamber. In yet another alternate embodiment, the cavitation fluid can be degassed initially outside of chamber 301 and then again within chamber 301.

In the embodiment illustrated in FIG. 3, a three-way valve 325 allows the system to be coupled to the ambient atmosphere via conduit 327 or to vacuum pump 321. It will be appreciated that three-way valve 325 can be replaced with a pair of two-way valves (not shown). Valve 329 provides a means for isolating the system from pump 321. Preferably a trap 331 is used to insure that cavitation fluid is not drawn into vacuum pump 321 or vacuum gauge 333. Preferably trap 331 is cooled so that any cavitation medium entering the trap condenses or solidifies. Vacuum gauge 333 is used to provide an accurate assessment of the system pressure. If the cavitation system becomes pressurized, prior to re-coupling the system to either vacuum gauge 333 or vacuum pump 321 the cavitation system pressure is bled down to an acceptable level using three-way valve 325.

A cavitation fluid filling system, not shown, is coupled to chamber 301 and used to fill the chamber to the desired level. It will be appreciated that the operating level for a particular cavitation chamber is based on obtaining the most efficient cavitation action. For example, while a spherical chamber may be most efficiently operated when it is completely full, a vertically aligned cylindrical chamber (e.g., the chamber shown in FIG. 3) may operate most efficiently when it is not completely full, thus providing a free cavitation liquid surface at the top of the chamber. The filling system may utilize a simple fill tube (e.g., conduit 327), a separate fluid reservoir, or other filling means. Regardless of the method used to fill the cavitation chamber, preferably the system is evacuated prior to filling, thus causing the cavitation medium to be drawn into the system (i.e., utilizing ambient air pressure to provide the pressure to fill the system).

Although not required, the filling system may include a circulatory system, such as that described in co-pending U.S. patent application Ser. No. 11/001,720, filed Dec. 1, 2004, entitled Cavitation Fluid Circulatory System for a Cavitation Chamber, the disclosure of which is incorporated herein for any and all purposes. Other components that may or may not be coupled to the cavitation fluid filling and/or circulatory system include bubble traps, cavitation fluid filters, and heat exchange systems. Further descriptions of some of these variations are provided in co-pending U.S. patent application Ser. No. 10/961,353, filed Oct. 7, 2004, entitled Heat Exchange System for a Cavitation Chamber, the disclosure of which is incorporated herein for any and all purposes.

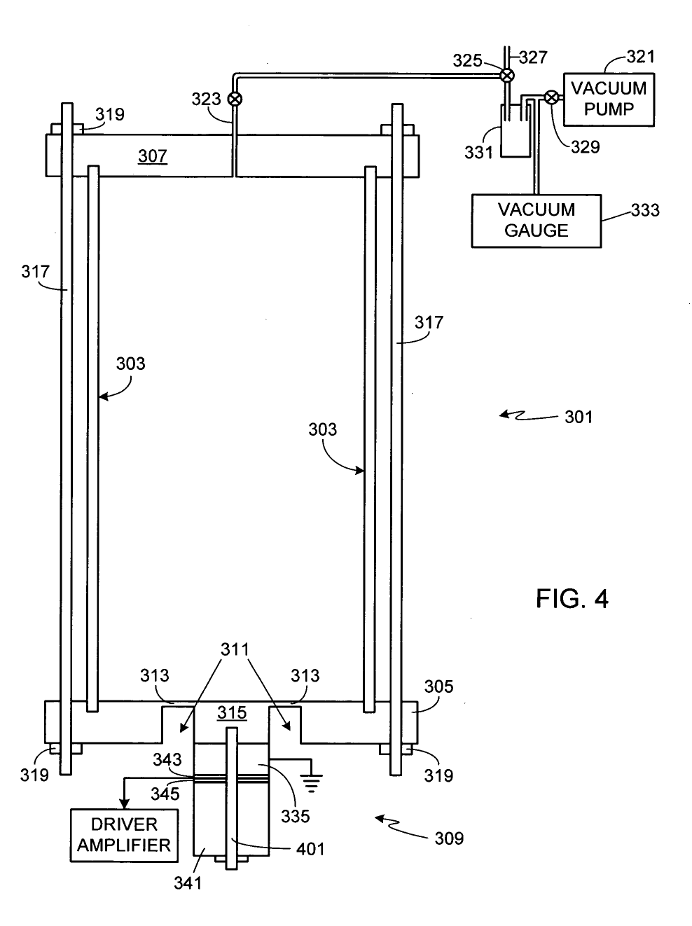

Although the invention is not limited to a specific number, type, mounting technique or mounting location for the acoustic driver, in the embodiment illustrated in FIG. 3 a single driver 309 is used. In this embodiment of the invention, head mass 335 of driver 309 is attached to portion 315 of end cap 305, referred to herein as a driver horn, horn portion 315 defined by groove 311. Preferably head mass 335 and horn 315 are coupled together with a threaded means 337 (e.g., an all thread), although other coupling means can be used such as epoxy, brazing, etc. A second threaded means 339 (e.g., a bolt or an all thread and nut assembly) couples head mass 335 to tail mass 341. Alternately, and as shown in FIG. 4, a single threaded means 401 (e.g., a bolt or an all thread and nut assembly) can be used to both assemble the driver and couple the driver to chamber horn 315. In between the head mass and the tail mass is a transducer, preferably a piezoelectric transducer, and more preferably a pair of piezoelectric transducers 343/345, as previously described relative to FIGS. 1 and 2.

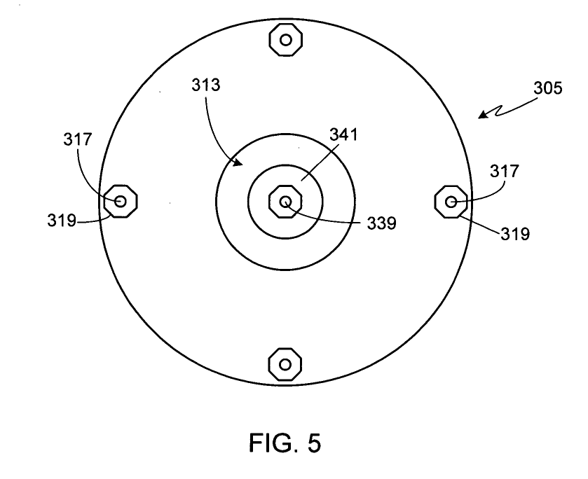

FIG. 5 is an end view of end cap 305, showing a different perspective of thinned region 313. The inventors have found that by varying the thickness of region 313 as well as the width of groove 311, the increase in achievable displacement for a given driver power can be controlled. Region 313 is very thin, preferably less than 0.25 inches, more preferably less than 0.050 inches, and still more preferably in the range of 0.030 inches to 0.020 inches. As a result of region 313 being very thin, horn region 315 is sufficiently flexible to insure efficient coupling of the acoustic energy of driver assembly 309 into the cavitation fluid contained within chamber 301. In a preferred embodiment, the width of groove 311 is in the range of a half to one times the thickness of end cap 305. Thus for an end cap thickness of 0.5 inches, the width of groove 311 is preferably between 0.25 and 0.5 inches.

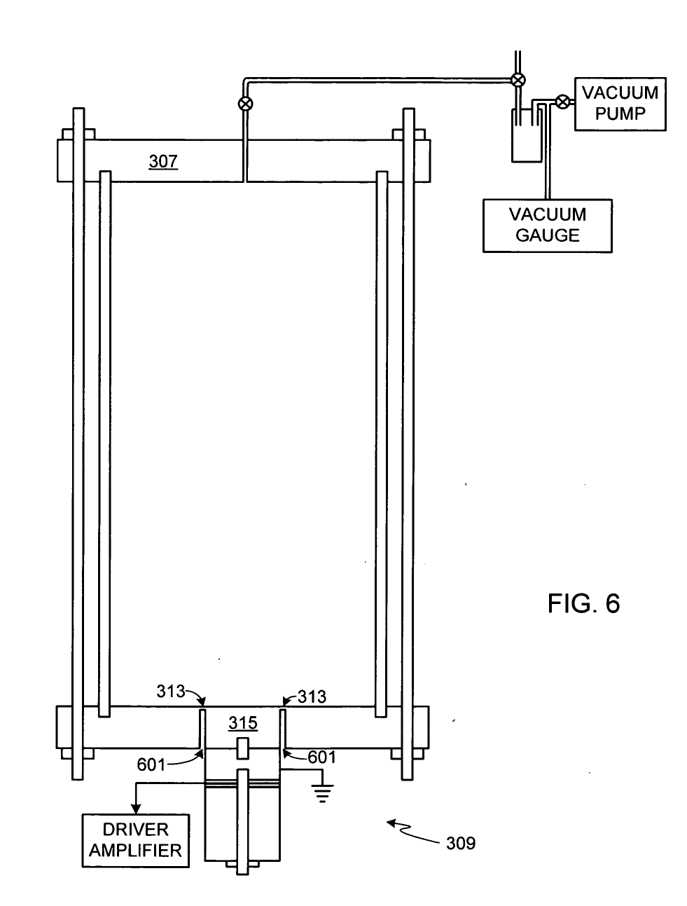

Under some circumstances, for example when either or both the drive power and the internal cavitation chamber pressure are high, the width of the groove is preferably more narrow than in the previous embodiment. For example, in the embodiment shown in FIG. 6, groove 601 is much narrower than groove 311 of FIG. 3. In particular in this embodiment groove 601 is approximately twice the width of region 313. In other words, in this embodiment the width of groove 601 is approximately 0.060 inches while the thickness of region 313 is approximately 0.030 inches. It will be appreciated that the present invention is not limited to a particular groove width, nor is the invention limited to a particular thickness for region 313 surrounding the driver horn.

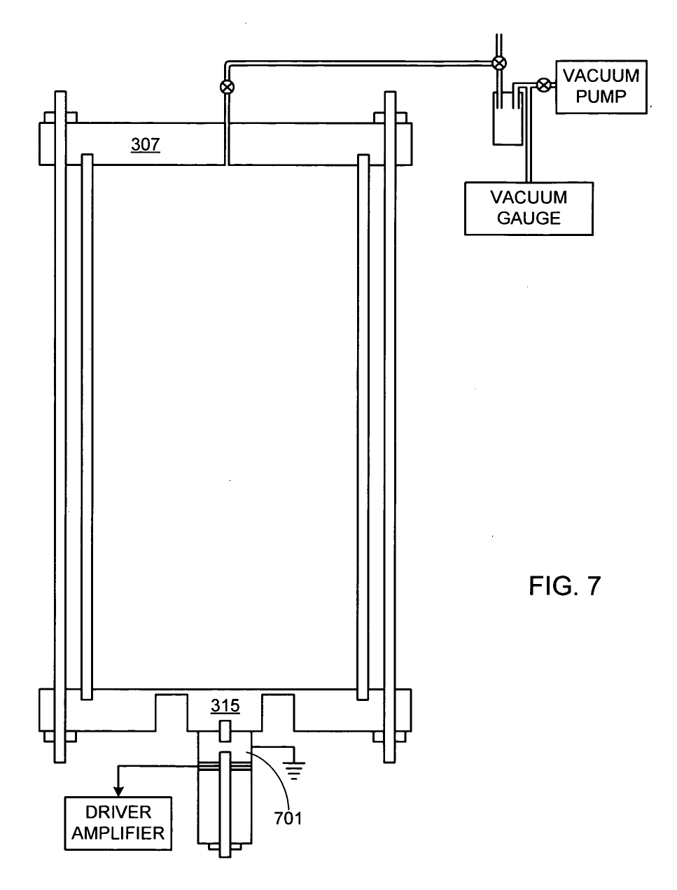

Although in the embodiments illustrated in FIGS. 3, 4 and 6 the head mass of the driver assembly has the same diameter as integral horn region 315, it should be understood that the invention does not require that these two regions have equivalent diameters. For example, in the embodiment shown in FIG. 7, head mass 701 has a smaller diameter than horn 315.

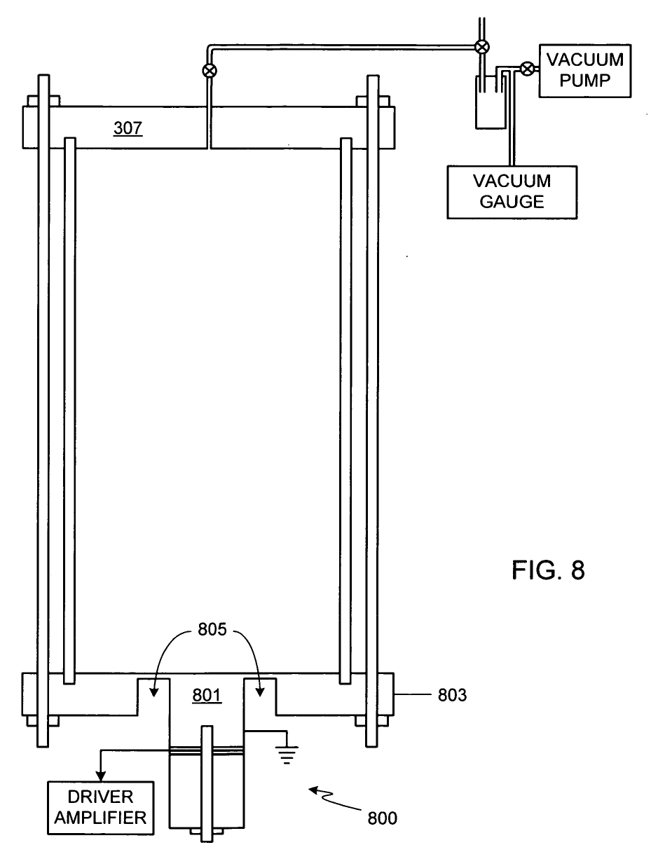

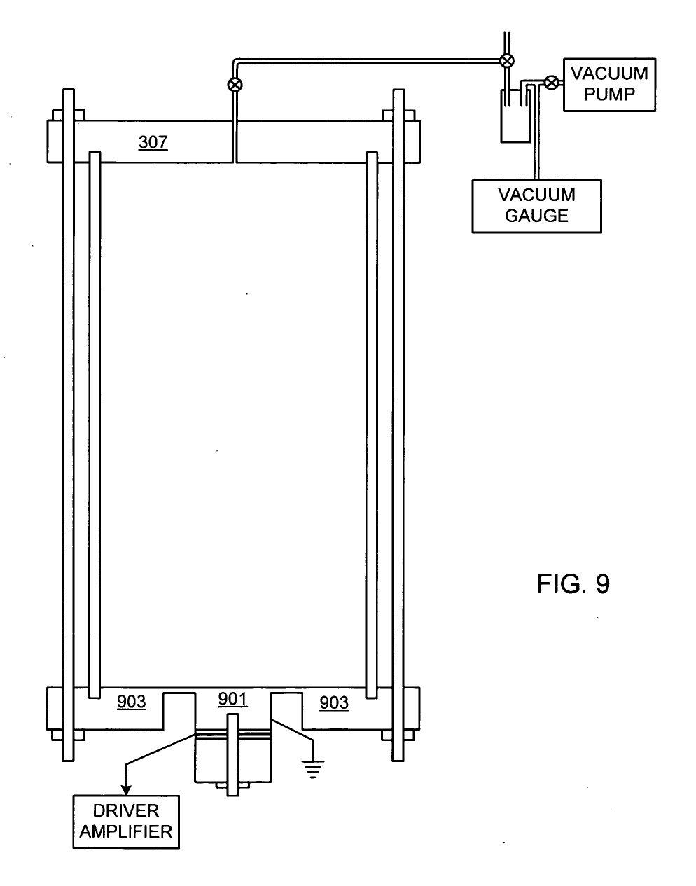

In the previously described embodiments, the head mass of the driver is separate from horn region 315 that is integrated into the chamber wall. In an alternate configuration illustrated in FIG. 8, these two structures are combined into a single element. More specifically, region 801 of chamber wall 803, surrounded by a groove 805, serves the dual purpose of horn and head mass. The remaining elements of driver assembly 800 (e.g., tail mass, transducers, etc.) are similar or the same as those of driver assembly 309. It will be appreciated that the thickness of region 801 does not have to be thicker than the bulk of the end cap (or cavitation wall). For example, as shown in the embodiment of FIG. 9, head mass/horn 901 is of the same thickness as portions 903 of the end cap.

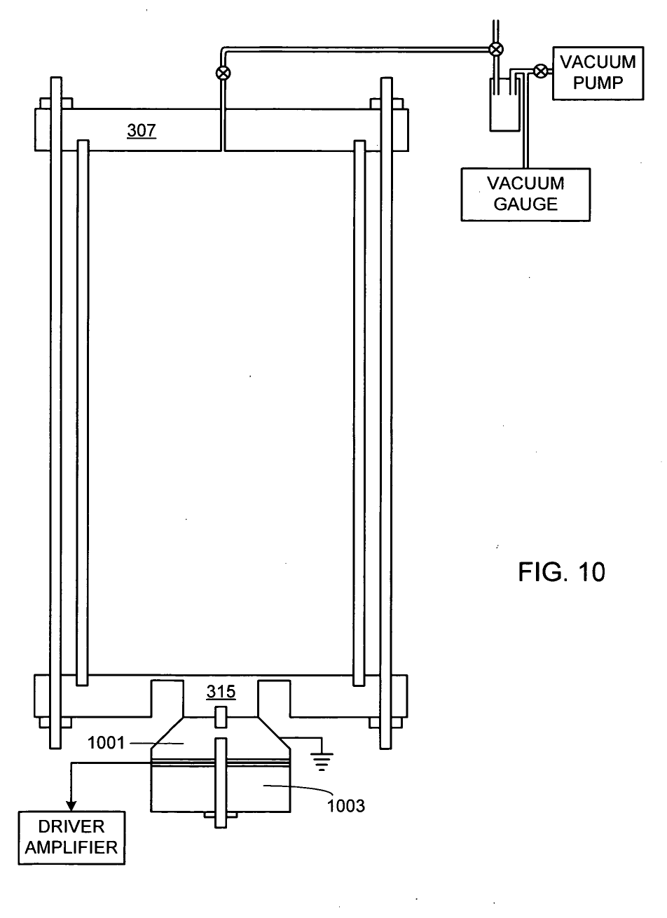

An advantage of the two-piece head mass and horn assembly shown in FIG. 3 is that it allows the shape of the head mass to be easily varied. For example, in the embodiment illustrated in FIG. 10, head mass portion 335 has been replaced with a shaped head mass portion 1001. Any of a variety of head mass shapes can be used. Tail mass 341 has similarly been replaced with a differently shaped tail mass 1003 in order to match the end surface diameter of head mass portion 1001, thus improving the performance of the piezoelectric transducers captured between the adjacent faces of the head mass and the tail mass.

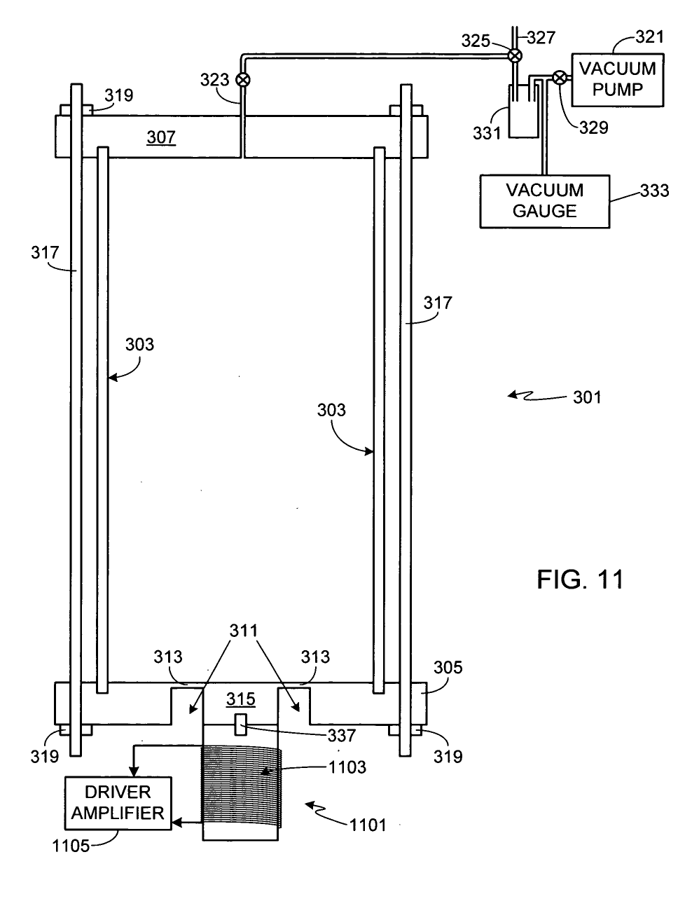

As described above, the present invention is not limited to piezoelectric transducers. For example, the invention can also utilize magnetostrictive transducers, simply replacing the head mass/piezoelectric transducer/tail mass assembly with a magnetostrictive transducer assembly. This aspect of the invention is illustrated in FIG. 11 which is identical to the embodiment shown in FIG. 3, except for the replacement of head mass 335, piezoelectric transducers 343 and 345, and tail mass 341 with magnetostrictive transducer 1101. The electromagnetic coils 1103 used by transducer 1101 are coupled to driver 30 amplifier 1105. In addition to the embodiment shown in FIG. 11, it should be understood that magnetostrictive transducers can also be used in place of the piezoelectric transducer assemblies of the other embodiments as well.

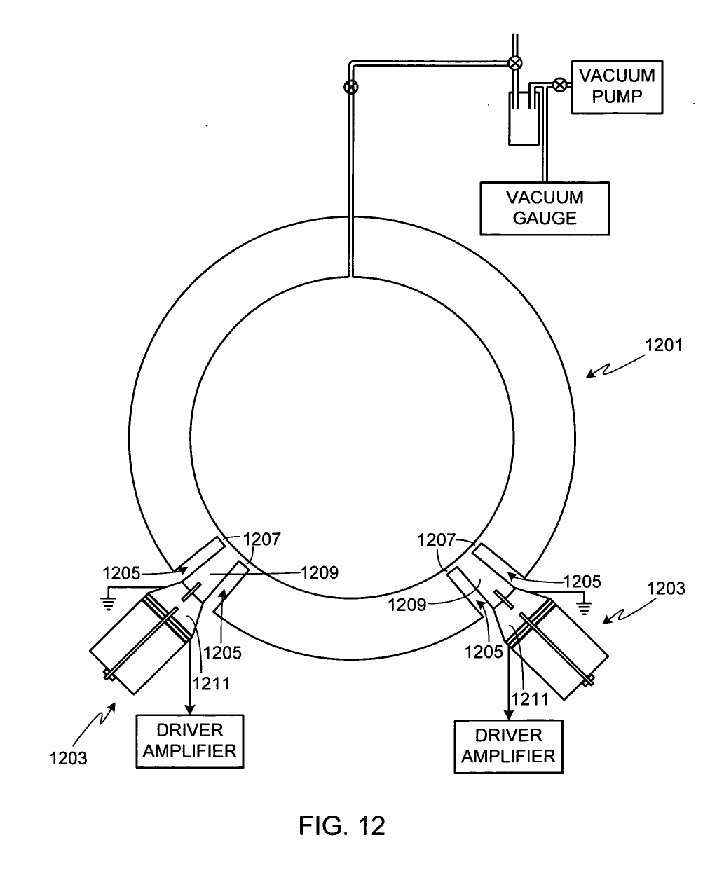

As previously noted, the present invention is not limited to a particular cavitation chamber configuration, nor is it limited to a particular number or configuration of driver assembly. For example, the embodiment illustrated in FIG. 12 includes a spherical cavitation chamber 1201 and a pair of driver assemblies 1203. As in the previous embodiments, a portion 1205 of the chamber wall has been removed, leaving a thin wall section 1207 surrounding driver horn 1209. Although driver assemblies 1203 can be configured with a single head mass/horn assembly as in the embodiments illustrated in FIGS. 8 and 9, preferably integral driver horn 1209 is separate from head mass 1211.

Although not required by the invention, preferably void filling material is included between some or all adjacent pairs of surfaces of the driver assembly and/or the driver assembly and the cavitation chamber, thereby improving the overall coupling efficiency and operation of the driver. Suitable void filling material should be sufficiently compressible to fill the voids or surface imperfections of the adjacent surfaces while not being so compressible as to overly dampen the acoustic energy supplied by the transducers. Preferably the void filling material is a high viscosity grease, although wax, very soft metals (e.g., solder), or other materials can be used.

As will be understood by those familiar with the art, the present invention may be embodied in other specific forms without departing from the spirit or essential characteristics thereof. Accordingly, the disclosures and descriptions herein are intended to be illustrative, but not limiting, of the scope of the invention which is set forth in the following claims.

What is claimed is:

1. A cavitation system, comprising:
a cavitation chamber, wherein a wall of said cavitation chamber is comprised of at least a first wall portion and a second wall portion, wherein said first wall portion defines a driver horn, and wherein said first wall portion and said second wall portion are separated by a groove in an exterior surface of said wall; and
an acoustic driver assembly coupled to said driver horn.

2. The cavitation system of claim 1, wherein a third wall portion defined by said groove is less than 0.25 inches thick.

3. The cavitation system of claim 1, wherein a third wall portion defined by said groove is less than 0.050 inches thick.

4. The cavitation system of claim 1, wherein a first thickness corresponding to said first wall portion and a second thickness corresponding to said second wall portion are equivalent.

5. The cavitation system of claim 1, wherein a first thickness corresponding to said first wall portion is greater than a second thickness corresponding to said second wall portion.

6. The cavitation system of claim 1, wherein said cavitation chamber further comprises a first end cap, a second end cap, a cylindrical portion and means for coupling said first end cap to said second end cap and capturing said cylindrical portion between said first and second end caps, and wherein said first end cap includes said cavitation chamber wall.

7. The cavitation system of claim 1, wherein said acoustic driver assembly further comprises:
a tail mass;
at least one transducer, wherein a first side of said at least one transducer is adjacent to said tail mass, and wherein a second side of said at least one transducer is adjacent to said driver horn; and
a means for assembling said acoustic driver assembly.

8. The cavitation system of claim 7, wherein said assembling means further comprises a centrally located threaded means coupling said tail mass and said at least one transducer to said driver horn, and wherein said centrally located threaded means is threaded into a corresponding threaded hole in said driver horn.

9. The cavitation system of claim 8, wherein said assembling means further comprises a threaded nut corresponding to said centrally located threaded means, and wherein said threaded nut compresses said tail mass and said at least one transducer against said driver horn.

10. The cavitation system of claim 8, further comprising an insulating sleeve surrounding at least a portion of said centrally located threaded means, wherein said insulating sleeve is interposed between said centrally located threaded means and said at least one transducer.

11. The cavitation system of claim 7, wherein said at least one transducer is comprised of a piezoelectric transducer.

12. The cavitation system of claim 7, wherein said at least one transducer is comprised of a first piezoelectric transducer and a second piezoelectric transducer, wherein adjacent surfaces of said first and second piezoelectric transducers have the same polarity.

13. The cavitation system of claim 1, wherein said acoustic driver assembly further comprises:
at least one transducer;
a tail mass, wherein a first side of said at least one transducer is adjacent to said tail mass;
a head mass, wherein a first side of said head mass is adjacent to a second side of said at least one transducer, and wherein a second side of said head mass is adjacent to said driver horn;
a means for coupling said head mass to said driver horn; and
a means for assembling said acoustic driver assembly.

14. The cavitation system of claim 13, wherein said coupling means further comprises a threaded means, wherein said threaded means is threaded into a first corresponding threaded hole in said driver horn and a second corresponding threaded hole in said head mass.

15. The cavitation system of claim 13, wherein said assembling means further comprises a threaded means coupling said tail mass and said at least one transducer to said head mass, and wherein said threaded means is threaded into a corresponding threaded hole in said head mass.

16. The cavitation system of claim 15, wherein said assembling means further comprises a threaded nut corresponding to said threaded means, wherein said threaded nut compresses said tail mass and said at least one transducer against said head mass.

17. The cavitation system of claim 15, further comprising an insulating sleeve surrounding at least a portion of said threaded means, wherein said insulating sleeve is interposed between said threaded means and said at least one transducer.

18. The cavitation system of claim 13, wherein said head mass is shaped.

19. The cavitation system of claim 13, wherein a diameter corresponding to said head mass is different from a diameter corresponding to said driver horn.

20. The cavitation system of claim 13, wherein said at least one transducer is comprised of a piezoelectric transducer.

21. The cavitation system of claim 13, wherein said at least one transducer is comprised of a first piezoelectric transducer and a second piezoelectric transducer, wherein adjacent surfaces of said first and second piezoelectric transducers have the same polarity.

22. The cavitation system of claim 1, wherein said acoustic driver assembly further comprises:
at least one transducer;
a tail mass, wherein a first side of said at least one transducer is adjacent to said tail mass;
a head mass, wherein a first side of said head mass is adjacent to a second side of said at least one transducer, and wherein a second side of said head mass is adjacent to said driver horn; and
a threaded means for assembling said acoustic driver assembly and coupling said acoustic driver assembly to said driver horn, wherein said threaded means is threaded into a corresponding threaded hole in said driver horn.

23. The cavitation system of claim 22, wherein said assembling means further comprises a threaded nut corresponding to said threaded means, wherein said threaded nut compresses said tail mass, said at least one transducer and said head mass against said driver horn.

24. The cavitation system of claim 22, further comprising an insulating sleeve surrounding at least a portion of said threaded means, wherein said insulating sleeve is interposed between said threaded means and said at least one transducer.

25. The cavitation system of claim 22, wherein said head mass is shaped.

26. The cavitation system of claim 22, wherein a diameter corresponding to said head mass is different from a diameter corresponding to said driver horn.

27. The cavitation system of claim 22, wherein said at least one transducer is comprised of a piezoelectric transducer.

28. The cavitation system of claim 22, wherein said at least one transducer is comprised of a first piezoelectric transducer and a second piezoelectric transducer, wherein adjacent surfaces of said first and second piezoelectric transducers have the same polarity.
